(19) United States
(12) Patent Application Publication
(10) Pub. No.: US 2004/0158784 A1
(43) Pub. Date: Aug. 12, 2004

(54) Microprocessor based self-diagnostic port

(75) Inventors: Zahi Said Abuhamdeh, Billerica, MA (US); Philip J. Pears, Westford, MA (US)

Correspondence Address: GORDON & JACOBSON, P.C., 65 WOODS END ROAD, STAMFORD, CT, 06905, US

(73) Assignee: TranSwitch Corporation

(21) Appl. No.: 10/647,018

(22) Filed: Aug. 22, 2003

Related U.S. Application Data
(60) Provisional application No. 60/445,407, filed on Feb. 6, 2003.

(51) Int. Cl. G01R 31/28

(52) U.S. Cl. 714/724

(57) ABSTRACT

An integrated circuit chip is provided with a JTAG TAP, an on-chip JTAG master coupled to the JTAG TAP and a microprocessor interface coupled to the JTAG master. This arrangement permits testing the integrated circuit chip without removing it from a circuit board or taking the circuit board out of service. It allows testing without regard to other chips on the same board. Preferably, the chip also has a conventional JTAG interface which is switchably uncouplable from the JTAG TAP.

### BACKGROUND OF THE INVENTION

1. Field of the Invention

The invention relates to testing integrated circuits. More particularly, the invention relates to an on-chip implementation of a JTAG (Joint Test Action Group) master which can effect a plurality of predefined tests of the chip without regard to other devices on the same circuit board.

2. State of the Art

Over the years printed circuit boards (PCBs) have grown in complexity. Advances in surface mount packaging and PCB manufacturing have resulted in smaller PCBs with chips spaced closer to each other than in the past. Thus, modern PCBs can not always be tested with traditional tools, e.g. physical test probes applied to the board externally.

In the 1980s, the Joint Test Action Group (JTAG) developed a specification for boundary scan testing (BST) that was later standardized as IEEE 1149.1. The BST can test pin connections without the use of physical test probes. The BST standard defines a serial protocol for accessing and controlling the signal-levels on the pins of a digital circuit, and has some extensions for testing the internal circuitry on the chip itself. All the signals between the chip's core logic and its pins are intercepted by a serial scan path known as the “Boundary Scan Register” (BSR). In normal system operation this path can transparently connect the core-logic signals to the pins and effectively become invisible. In external-test mode, it can disconnect the core-logic from the pins, drive the output pins by itself, and read and latch the states of the input pins. In internal-test mode, it can disconnect the core-logic from the pins, drive the core-logic input signals by itself, and read and latch the states of the core-logic output signals. The interface to the BST is via five pins and an on-chip TAP (test access port) controller state machine.

The JTAG interface uses the following five dedicated signals which must be provided on each chip that supports the standard:

TRST, a Test-ReSeT input which initializes and disables the test interface;

TCK, the Test CLocK input which controls the timing of the test interface independently from any system clocks. TCK is pulsed by the equipment controlling the test and not by the tested device. It can be pulsed at any frequency (up to a maximum of some MHz). It can be even pulsed at varying rates;

TMS, the Test Mode Select input which controls the transitions of the test interface state machine;

TDI, the Test Data Input line, which supplies the data to the JTAG registers (Boundary Scan Register, Instruction Register, or other data registers); and

TDO, the Test Data Output line, which is used to serially output the data from the JTAG registers to the equipment controlling the test. It carries the sampled values from the boundary scan chain (or other JTAG registers) and propagates them to the next chip in the serial test circuit.

The normal organization of the test circuit on a board that incorporates several chips with JTAG support is to connect TRST, TCK, and TMS to every chip in parallel, and to connect TDO from one chip to TDI of the next in a single loop. This presents a single JTAG test interface for the board. It is possible to provide individual access to each chip on the board but it would require the use of five board pins for each chip.

Although the JTAG interface has proved to be very effective, it is limited in some ways. First, in order to test a single chip on a PCB is may be necessary to remove the chip from the board. Although it is possible to test individual chips on a board without removing them from the board, it is necessary to take the board out of service to perform the tests. Further, in order to implement JTAG tests, the board developer must be aware of various parameters for each of the chips on the board.

On the chip level, JTAG has been used by manufacturers to test a chip for compliance with the manufacturer's specifications. It would be useful for board developers to be able to perform the same tests that the chip manufacturer uses to determine whether the chip is operating properly. It would also be desirable for the chip manufacturer to provide the board developer with a turn-key testing solution. These objects, however, are not easily achievable. In order to provide a turn-key solution for a chip which is being used on the developer's board, the chip manufacturer would need to know the particulars about the board and how the JTAG interface(s) are implemented on the board. This is impractical because chip manufacturers want to make their chips as versatile as possible so that they may be used on many different board applications.

### SUMMARY OF THE INVENTION

It is therefore an object of the invention to provide methods and apparatus for enabling diagnostic testing of a chip on a circuit board.

It is also an object of the invention to provide methods and apparatus for enabling diagnostic testing of a chip on a circuit board which do not require removing the chip from the board or taking the board out of service.

It is another object of the invention to provide methods and apparatus for enabling diagnostic testing of a chip on a circuit board which enable the chip manufacturer to provide a single testing solution for the chip which will work properly regardless of the board on which the chip is used.

It is still another object of the invention to provide methods and apparatus for selecting between standard JTAG testing and testing according to the invention.

In accord with these objects which will be discussed in detail below, the present invention provides an application specific integrated circuit (ASIC) having a JTAG interface and a microprocessor interface. According to the invention, the ASIC is also provided with an on-chip JTAG master which is coupled to the JTAG interface and the microprocessor interface. The microprocessor interface is provided with a plurality of registers which are mapped to the five JTAG signals and additional registers which are used to conduct a plurality of tests. The methods of the invention include controlling the on-chip JTAG master via an off-chip microprocessor coupled to the microprocessor interface.

Using the invention, diagnostic tests of the chip can be performed without removing the chip from the board and without removing the board from service. Board developers and device maintenance personnel can perform the same diagnostic tests as the manufacturer to determine whether the chip is performing according to specification. The invention therefore allows more accurate tests of in-service boards which are part of a larger device, e.g. a telecommunications switch. In addition, since the board does not need to be taken out of service, the invention can be advantageously used to create single chip systems. With the invention, a chip manufacturer can supply developers with a set of diagnostic programs which can be used to test the chip regardless of how the board carrying the chip is designed. The present implementation of the invention allows the same JTAG master and microprocessor interface to be used on many different chips without modification.

Additional objects and advantages of the invention will become apparent to those skilled in the art upon reference to the detailed description taken in conjunction with the provided figures.

### BRIEF DESCRIPTION OF THE DRAWINGS

FIG. 1 is a high level block diagram of an ASIC according to the invention; and

FIG. 2 is a high level block diagram of a synchronization circuit which is used to switch between the microprocessor control of the JTAG TAP and traditional control of the JTAG TAP.

### DETAILED DESCRIPTION OF THE PREFERRED EMBODIMENTS

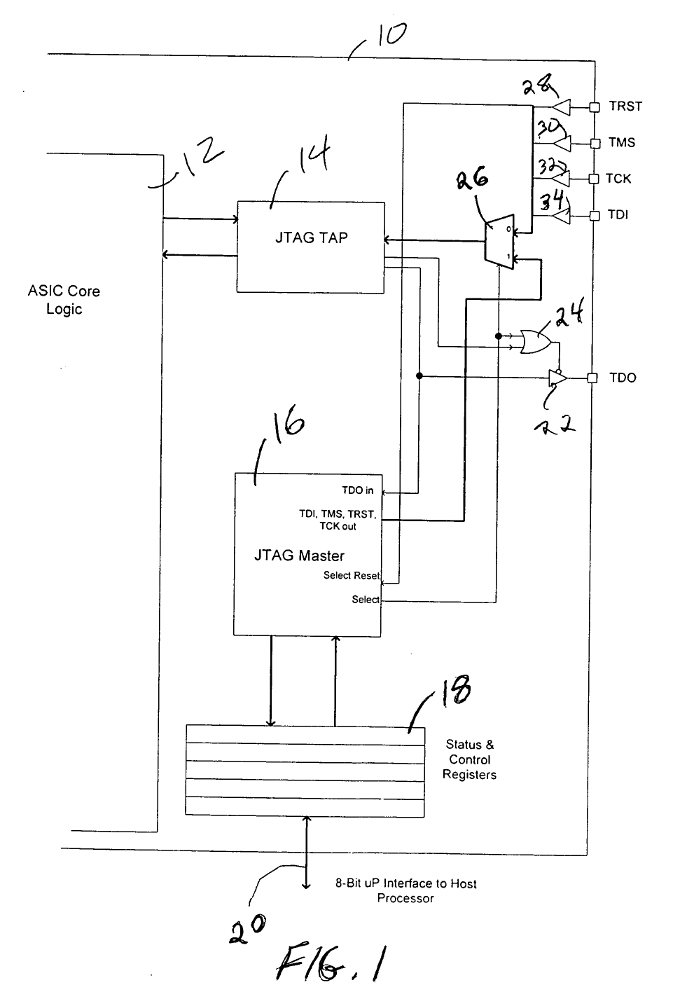

Referring now to FIG. 1, an ASIC 10 according to the invention includes core logic 12 which provides the primary functions of the ASIC and which is coupled to a plurality of pins (not shown). In addition, the ASIC 10 is provided with a standard JTAG TAP 14 which is coupled to the core logic 12 and selectively coupled to the standard JTAG five pin interface TRST, TMS, TCK, TDI; and TDO. According to the invention an on-chip JTAG Master 16 is selectively coupled to the JTAG TAP 14. The JTAG master 16 is coupled to an 8-bit microprocessor interface 20 via a plurality of status and control registers 18.

More particularly the TDO output of the JTAG TAP is coupled to a TDO input of the JTAG Master and via a switch 22 to the standard TDO pin on the chip 10. The switch 22 is operated by output from an OR gate 24 which receives input from both the JTAG TAP (TDO output enable) and a select signal from the JTAG Master. The JTAG master 16 outputs TRST, TMS, TCK, and TDI signals to a switch 26 which is also coupled the TRST, TMS, TCK, and TDI pins. The select signal from the JTAG Master 16 activates both switches 22 and 26 to override the JTAG pins on the chip and substitute the JTAG Master for them. The JTAG Master also receives a select reset signal from the TRST pin. As shown in the Figures, the TRST, TMS, TCK, and TDI pins are each associated with an input buffer 28, 30, 32, 34.

The status and control registers 18 include the following registers identified in Table 1.

TABLE 1

| Register | MP | |
|---|---|---|
| Name | Access | Function |
| TCK_Divider | R/W | A clock divider number (divisor) used to |
| | | create a 10 MHz TCK from the |
| | | system clock |
| Counter | R/W | 6-Bit shift count register. |
| TDI_FIFO_B0 | R/W | Byte 0 of a (5x8 deep) FIFO containing |
| | | TDI data to send to the TAP |
| TDI_FIFO_B1 | R/W | Byte 1 of a (5x8 deep) FIFO containing |
| | | TDI data to send to the TAP |
| TDI_FIFO_B2 | R/W | Byte 2 of a (5x8 deep) FIFO containing |
| | | TDI data to send to the TAP |
| TDI_FIFO_B3 | R/W | Byte 3 of a (5x8 deep) FIFO containing |
| | | TDI data to send to the TAP |
| TDI_FIFO_B4 | R/W | Byte 4 of a (5x8 deep) FIFO containing |
| | | TDI data to send to the TAP |
| TMS_FIFO_B0 | R/W | Byte 0 of a (5x8 deep) FIFO containing |
| | | TMS data to send to the TAP |
| TMS_FIFO_B1 | R/W | Byte 1 of a (5x8 deep) FIFO containing |
| | | TMS data to send to the TAP |
| TMS_FIFO_B2 | R/W | Byte 2 of a (5x8 deep) FIFO containing |
| | | TMS data to send to the TAP |
| TMS_FIFO_B3 | R/W | Byte 3 of a (5x8 deep) FIFO containing |
| | | TMS data to send to the TAP |
| TMS_FIFO_B4 | R/W | Byte 4 of a (5x8 deep) FIFO containing |
| | | TMS data to send to the TAP |
| TDO_FIFO_B0 | R | Byte 0 of a (5x8 deep) FIFO containing |
| | | TDO data received from the TAP |
| TDO_FIFO_B1 | R | Byte 1 of a (5x8 deep) FIFO containing |
| | | TDO data received from the TAP |
| TDO_FIFO_B2 | R | Byte 2 of a (5x8 deep) FIFO containing |
| | | TDO data received from the TAP |
| TDO_FIFO_B3 | R | Byte 3 of a (5x8 deep) FIFO containing |
| | | TDO data received from the TAP |
| TDO_FIFO_B4 | R | Byte 4 of a (5x8 deep) FIFO containing |
| | | TDO data received from the TAP |
| Start | R/W | Start bit is set to trigger a transfer |
| | | between the microprocessor and the TAP |
| | | via the JTAG Master. This bit clears |
| | | the End bit. |
| End | R | When a transfer is completed, this bit |
| | | is set. |
| JM_TRSTN | R/W | The value of TRST driven by the |
| | | microprocessor interface. Initializes to |
| | | logical ‘O’. |
| TDI_Loop_Back | R/W | This bit loops back the TDI FIFO output, |
| | | back into the TDO FIFO input. Used to |
| | | test the interface. |
| TMS_Loop_Back | R/W | This bit loops back the TMS FIFO output, |
| | | back into the TDO FIFO Input. Used to |
| | | test the interface |
| TRSTN_Sample | R | This bit samples what the microprocessor |
| | | interface is driving into the TAP |
| MP_CNTRL | R/W | This bit switches TAP control from pins |
| | | to the on-chip JTAG master |

According to the presently preferred embodiments, the ASICs according to the invention are designed for use in telecommunications switching. These chips are generally provided with a microprocessor interface which is connected to a host for configuring the telecommunications switch, e.g. provisioning circuits, establishing quality of services parameters, managing queues, etc. The present invention makes use of this existing microprocessor interface to control the new on-chip JTAG master via the registers described above which coordinate the handshake between the host processor and the JTAG master, and issue instructions and operations to the target on-chip TAP state machine.

Some of the features which are available via the microprocessor interface include memory built-in self-test (BIST), logic BIST, manufacturing ID codes, memory BIS.TT diagnostic data, special configuration registers, RAM repair information, etc.

Two FIFOs are used to control the TAP, the TDI FIFO and the TMS FIFO. The TDI (test data input) FIFO is filled with the data to be used in the test and the TMS (test mode select) FIFO is filled with control information associated with each TDI bit that will be applied to the TAP. The six-bit Counter is initialized with the six-bit binary representation of the number of bits to be shifted. As the TMS and TDI FIFOS are each 5×8, the maximum number of bits to be shifted is forty. Once these three registers are initialized, the Start bit is set and the JTAG master state machine reads each bit from the TDI & TMS FIFOs, and places them sequentially on the TDI and TMS inputs of the TAP. At the same time, the JTAG master shifts TDO bits into the TDO FIFOs where they can be read by the microprocessor. When the counter expires, the End bit is set, and the last bit of the TMS register is held on the TAP inputs.

According to the invention, the FIFOs are kept small to conserve space on the chip. In the presently preferred embodiment the FIFOs are no larger than 40 bits. However, by exploiting features of the TAP standard, operations larger than 40 bits can be achieved.

The TAP state machine is designed to allow four states to be held in place without shifting in new data. These states, which are held in place based on the TMS value, are as follows:

State 1: Test-Logic-Reset—This clears all the internal states of the TAP. Not used during test.

State 2: Run-Test-Idle—This state is the ‘No-Op’ equivalent for the TAP. No operation occurs, but active tests can still be running inside the ASIC. This state will not interfere with them, even though, the tests were initiated by the TAP.

State 3: Pause-IR—This state is a pause in the shift of the IR. From this state, the user has the option to go back to shift the IR some more bits, or exit and update the IR.

State 4: Pause-DR—This state is similar to the Pause-IR, but used for the internal Data Register. So, by loading the TMS & TDI fifos with a sequence of bits, the TAP can be cycled through its state elements, and held into one of the above states, depending on what needs to be done.

The following sequence, when loaded into the TMS & TDI FIFOs, will take the TAP out of Test-Logic-Reset state and place it in the Run-Test-Idle: state. It will also, hold the TMS to a value of ‘1’, which will keep the TAP in the Run-Test-Idle state.

TMS_Fifo: 00

TDI_Fifo: XX

Count: 2

The following sequence will load a sequence of 40-bits into the DR register and read the 40 DR status bits into the TDO FIFO. When the first operation is completed, the TAP will be held in the Pause-DR state when TMS is ‘0’, then next operation set will complete the shift, and put the TAP back into the Run-Test-Idle state (assuming it starts in the Run-Test-Idle state):

| | |
|---|---|
| TMS_Fifo: | 1000 0000 0000 0000 0000 0000 0000 0000 0000 0010 |
| TDI_Fifo: | XXX0 1234 5678 9012 3456 7890 1234 5678 9012 345X |
| Count: 40 | |

The resulting state sequence is from Run-Test-idle to Select-DR-Scan to Capture-DR to Shift-DR (36 times) to Exit1-DR to Pause-DR (N times). This will pause the shifting of the DR for as long as it takes the microprocessor to read the DR status bits from the TDO FIFO and to initialize the next new transaction.

The following sequence will shift from Pause-DR to Exit2-DR to Shift-DR (6 times) to Exitl-DR to Update-DR to Run-Test-Logic (N times).

TMS_Fifo: 1000 0001 1000

TDI_Fifo: XX45 6789 XXXX

Count: 12

These operation sets are a subset of the full capability of the TAP, but are sufficient to load/unload all the internal TAP states including the IR and device ID registers.

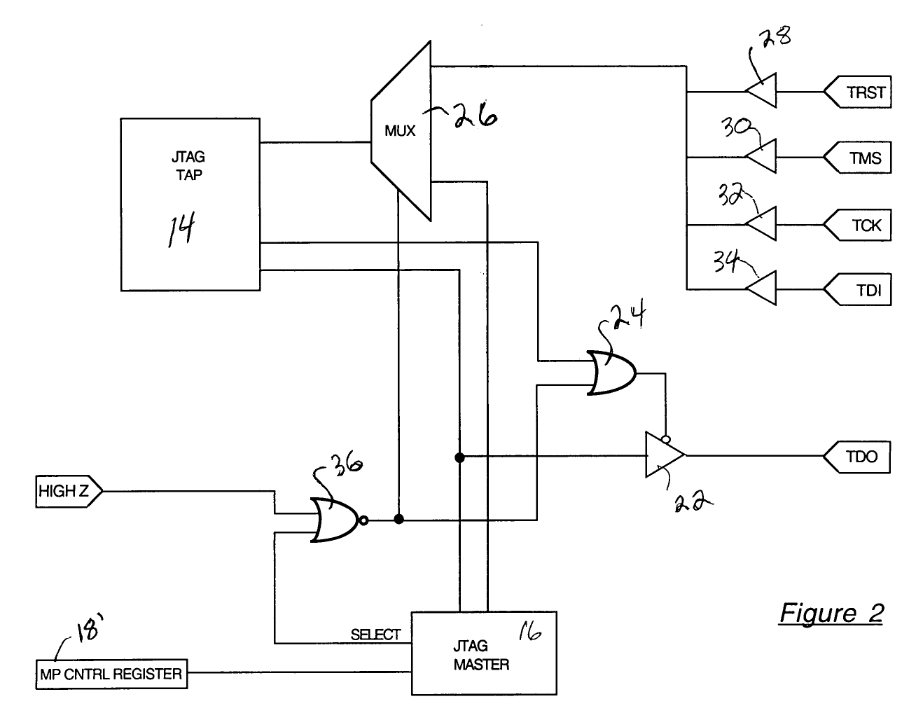

The switching mechanism, shown generally in FIG. 1 at 22, 24, 26, is designed to default to the normal JTAG interface. When the microprocessor is to take control of the TAP, a signal internal to the system is used to generate the switch. This signal is identified as “Select” in the JTAG master 16. Implementation of this signal may cause a problem if the system has not been initialized, and a bad value might be issued that makes the TAP inaccessible to the outside controls. FIG. 2 shows the synchronization circuit that insures the proper operation of both the normal JTAG TAP & the microprocessor interface.

As shown in FIG. 2, the select signal from the JTAG master 16, which is controlled by the contents of MP CNTRL REGISTER 18′, is NORed with a board level test pin. In FIG. 2 this pin is labeled “HIGH Z”, but any other board level test pin could be used. This pin is normally asserted (driven to 0) when the chip is operational. The circuit behaves in the following manner:

For tests run on the tester, the tests will strictly rely on the TAP being driven from the primary I/O pins. By asserting the HIGH Z pin to 1, the output of the NOR gate will always be 0, causing the standard JTAG interface to control the TAP. This requires that the HIGH Z pin be considered an IEEE 1149 compliance pin during any JTAG activity, while the ASIC is in stand alone mode.

For tests run in a system, tests will require that the HIGH Z pin be driven to 0, and the MP CNTRL REGISTER will select the source controlling the TAP. The MP CNTRL REGISTER is initialized to 1 with the microprocessor interface at the time the microprocessor interface is initialized. As such, the in-system TAP will default on power up to control by the external pins, and can be selected by the microprocessor to be controlled by on board signals from the JTAG master.

A prototype of the invention was synthesized for 0.18 μm and 0.13 μm TSMC Artisan Libraries. The resulting area of this block is approximately 5000 gates which represents a very minimal area overhead in the state of the art.

Referring once again to Table 1, the microprocessor interface can also be tested for correctness of operation. The interface can be placed into loop-back where either the TMS FIFO or the TDI FIFO is fed into the TDO FIFO. This loop back scheme allows the microprocessor interface to fully test bus accesses and the FIFOs used to drive the TAP. TRST can be sampled through the TRST_sample register, and its value confirmed.

There have been described and illustrated herein an integrated circuit with an on-chip JTAG master coupled to a microprocessor interface. While particular embodiments of the invention have been described, it is not intended that the invention be limited thereto, as it is intended that the invention be as broad in scope as the art will allow and that the specification be read likewise. It will therefore be appreciated by those skilled in the art that yet other modifications could be made to the provided invention without deviating from its spirit and scope as so claimed.

1. An integrated circuit chip, comprising:
a) core logic;
b) an on-chip JTAG TAP coupled to said core logic;
c) an on-chip JTAG master coupled to said JTAG TAP; and
d) an on-chip microprocessor interface coupled to said JTAG master.

2. The chip according to claim 1, further comprising:
e) a plurality of registers coupled to said microprocessor interface and to said JTAG master.

3. The chip according to claim 2, wherein:
said plurality of registers includes a TDI FIFO, a TMS FIFO, a TDO FIFO, and a counter register.

4. The chip according to claim 3, wherein:
said plurality of registers includes a start bit register and an end bit register.

5. The chip according to claim 1, wherein:
said chip has more than five pins and five of said pins are coupled to said on-chip JTAG TAP forming a JTAG interface to said chip.

6. The chip according to claim 5, further comprising:
e) switching means for selectively decoupling said JTAG interface from said JTAG TAP.

7. The chip according to claim 6, wherein:
said switching means is coupled to and controllable by said JTAG master.

8. The chip according to claim 7, wherein:
said switching means couples said JTAG master to said JTAG TAP when said JTAG interface is decoupled from said JTAG TAP, and
said switching means couples said JTAG interface to said JTAG TAP when said JTAG master is decoupled from said JTAG TAP.

9. An integrated circuit chip, comprising:
a) core logic;
b) an on-chip JTAG TAP coupled to said core logic;
c) an on-chip JTAG interface selectively coupled to said JTAG TAP;
d) an on-chip microprocessor interface selectively coupled to said JTAG TAP; and
e) switching means for selectively coupling said JTAG interface and said microprocessor interface to said JTAG TAP.

10. The chip according to claim 9, wherein:
said switching means operates to decouple said JTAG interface from said JTAG TAP when said microprocessor interface is coupled to said JTAG TAP, and
said switching means operates to decouple said microprocessor interface from said JTAG TAP when said JTAG interface is coupled to said JTAG TAP.

11. The chip according to claim 9, wherein:
said microprocessor interface includes a plurality of registers.

12. The chip according to claim 9, wherein:
said switching means is controllable via said microprocessor interface.

13. The chip according to claim 12, further comprising:
f) a switching means enable interface for receiving a signal to enable said switching means, wherein
said switching means is inoperable without receiving said signal.

14. The chip according to claim 13, wherein:
in the absence of said signal said switching means decouples said microprocessor interface from said JTAG TAP and couples said JTAG interface to said JTAG TAP.

15. The chip according to claim 11, wherein:
said plurality of registers includes a TDI FIFO, a TMS FIFO, a TDO FIFO, and a counter register.

16. The chip according to claim 15, wherein:
said TDI FIFO and said TMS FIFO each being N-bits in size, and
said microprocessor interfare includes means for performing TAP operations having bit counts in excess of N-bits.

17. The chip according to claim 16, wherein:
means for performing TAP operations having bit counts in excess of N-bits includes means for cycling said TAP through state elements and holding it in one of four states.

18. The chip according to claim 17, wherein:
said four states include Test-logic Reset, Run-Test Idle, Pause-IR, and Pause-DR.

19. An integrated circuit chip, comprising:
a) core logic;
b) an on-chip JTAG TAP coupled to said core logic;
c) an on-chip JTAG master selectively coupled to said JTAG TAP;
d) an on-chip JTAG interface selectively coupled to said JTAG TAP; and
e) switching means for selectively coupling said JTAG master and said JTAG interface to said JTAG TAP.

20. The chip according to claim 19, wherein:
said switching means operates to decouple said JTAG interface from said JTAG TAP when said JTAG master is coupled to said JTAG. TAP, and
said switching means operates to decouple said JTAG master from said JTAG TAP when said JTAG interface is coupled to said JTAG TAP.
